(19) United States
(12) Patent Application Publication
(10) Pub. No.: US 2026/0165191 A1
(43) Pub. Date: Jun. 11, 2026

(54) SEMICONDUCTOR PACKAGE

(71) Applicant: SAMSUNG ELECTRONICS CO., LTD., Suwon-si (KR)

(72) Inventor: Hansae LIM, Suwon-si (KR)

(73) Assignee: SAMSUNG ELECTRONICS CO., LTD., Suwon-si (KR)

(21) Appl. No.: 19/410,400

(22) Filed: Dec. 5, 2025

(30) Foreign Application Priority Data
Dec. 11, 2024 (KR) 10-2024-0184075

(51) Int. Cl. H10W 74/10; H10W 20/20; H10W 72/90; H10W 74/43; H10W 74/47; H10W 90/00; H10W 90/26

(52) U.S. Cl. CPC H10W 74/121; H10W 90/26; H10W 90/722; H10W 90/724; H10W 20/211; H10W 72/9445; H10W 74/43; H10W 74/47

(57) ABSTRACT

A semiconductor package includes a package substrate; a first semiconductor chip including a first substrate, a through electrode penetrating the first substrate, a first chip pad on a first surface of the first substrate and electrically connected to the through electrode, a protective pattern on the first surface, and a first passivation layer on the first surface and exposing the first chip pad and the protective pattern, wherein the first surface faces the package substrate, and the first semiconductor chip is connected to the package substrate via a first conductive bump disposed on the first chip pad; a second semiconductor chip stacked on the first semiconductor chip; and a molding member covering the first and second semiconductor chips on the package substrate. The molding member has a first molding portion disposed in a space between the package substrate and the first semiconductor chip and contacting the protective pattern.

### CROSS-REFERENCE TO RELATED APPLICATION

This application claims priority under 35 U.S.C. § 119 to Korean Patent Application No. 10-2024-0184075, filed on Dec. 11, 2024 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of different chips stacked on a package substrate and a method for manufacturing the same.

### 2. Description of the Related Art

As a passivation layer of a wafer becomes thicker, it becomes difficult to implement a thin package and control warpage that occurs during a package manufacturing process. In particular, photosensitive polyimide (PSPI), which is used as the outermost insulating layer, has a high coefficient of thermal expansion (CTE) compared to silicon, which is disadvantageous in terms of a package manufacturing process. In a chip stack package using a through silicon via (TSV), a thin silicon nitride layer with a low coefficient of thermal expansion may be used as the outermost insulating layer. However, in terms of the bonding strength between epoxy and a chip interface, the bonding strength may be relatively lower than that of the photosensitive polyimide, and there is a problem that delamination defects occur in a hygroscopic or high-temperature environment.

### SUMMARY

Example embodiments provide a semiconductor package having a structure that can implement a thin package and prevent delamination defects in a hygroscopic environment.

According to example embodiments, a semiconductor package includes a package substrate; a first semiconductor chip including a first substrate having a first surface and a second surface opposite to the first surface, a through electrode penetrating the first substrate, a first chip pad disposed on the first surface and electrically connected to the through electrode, a protective pattern disposed on the first surface, and a first passivation layer disposed on the first surface and exposing the first chip pad and the protective pattern, wherein the first surface faces the package substrate, and the first semiconductor chip is connected to the package substrate via a first conductive bump disposed on the first chip pad; a second semiconductor chip stacked on the first semiconductor chip and electrically connected to the through electrode; and a molding member covering the first semiconductor chip and the second semiconductor chip on the package substrate, the molding member having a first molding portion that is disposed in a space between the package substrate and the first semiconductor chip and contacts the protective pattern.

According to example embodiments, a semiconductor package includes a package substrate; a first semiconductor chip including a first substrate, a first wiring layer disposed on a first surface of the first substrate and having a first redistribution pad and a second redistribution pad, a first chip pad disposed on the first redistribution pad, a protective pattern disposed on the second redistribution pad, and a first passivation layer disposed on the first wiring layer and exposing the first chip pad and the protective pattern, wherein the first surface faces the package substrate, and the first semiconductor chip is connected to the package substrate via a first conductive bump disposed on the first chip pad; and a molding member covering the first semiconductor chip on the package substrate, the molding member having a first molding portion that is disposed in a space between the package substrate and the first semiconductor chip and surrounds the first conductive bump. The first molding portion of the molding member is in contact with the protective pattern, and the protective pattern includes an organic layer.

According to example embodiments, a semiconductor package includes a package substrate; a first semiconductor chip including a first substrate, a through electrode penetrating the first substrate, a first wiring layer disposed on a first surface of the first substrate and having a first redistribution pad and a second redistribution pad, and a first chip pad disposed on the first redistribution pad, a protective pattern disposed on the second redistribution pad, and a first passivation layer disposed on the first wiring layer and exposing the first chip pad and the protective pattern, wherein the first surface faces the package substrate, and the first semiconductor chip is connected to the package substrate via a first conductive bump disposed on the first chip pad; a second semiconductor chip including a second substrate, a second chip pad disposed on a third surface of the second substrate, and a second passivation layer disposed on the third surface and exposing the second chip pad, wherein the third surface faces the first semiconductor chip, and the second semiconductor chip is connected to the first semiconductor chip via a second conductive bump disposed on the second chip pad; a molding member covering the first semiconductor chip and the second semiconductor chip on the package substrate, the molding member having a first molding portion that is disposed in a space between the package substrate and the first semiconductor chip and contacts the protective pattern, and a second molding portion that is disposed in a space between the first semiconductor chip and the second semiconductor chip and surrounds the second conductive bump; and a plurality of outer connection members on a lower surface of the package substrate.

According to example embodiments, a semiconductor package may include a first semiconductor chip and a second semiconductor chip sequentially stacked on a package substrate. The first semiconductor chip may include a first passivation layer that is provided on a first surface of a first substrate and exposes a first chip pad and a protective pattern. The first semiconductor chip may be arranged such that the first surface faces the package substrate and may be stacked on the package substrate via first conductive bump formed on the first chip pad. A portion of a molding member including EMC may fill a space between the package substrate and the first semiconductor chip and may be in contact with the protective pattern.

The outermost protection layer of the first passivation layer may include silicon nitride (SiN). Since silicon nitride (SiN) has relatively low interfacial bonding strength with EMC, peeling defects may occur in a hygroscopic environment. The protective pattern including organic solderability preservative may react with epoxy to form a strong bond. Accordingly, the protective pattern may come into contact with the molding portion to increase the bonding strength between the silicon nitride (SiN) and the EMC interface, thereby preventing peeling defects.

### BRIEF DESCRIPTION OF THE DRAWINGS

Example embodiments will be more clearly understood from the following detailed description taken in conjunction with the accompanying drawings. FIGS. 1 to 21 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating a first passivation layer of the first semiconductor chip in FIG. 1.

FIGS. 4 to 18 are views illustrating a method of manufacturing a semiconductor package in accordance with example embodiments.

FIG. 19 is a cross-sectional view illustrating a semiconductor package in accordance with example embodiments.

FIG. 20 is an enlarged cross-sectional view illustrating portion ‘I” in FIG. 19.

FIG. 21 is a plan view illustrating a first semiconductor chip of a semiconductor package in accordance with example embodiments.

### DETAILED DESCRIPTION OF EXAMPLE EMBODIMENTS

Hereinafter, example embodiments will be explained in detail with reference to the accompanying drawings.

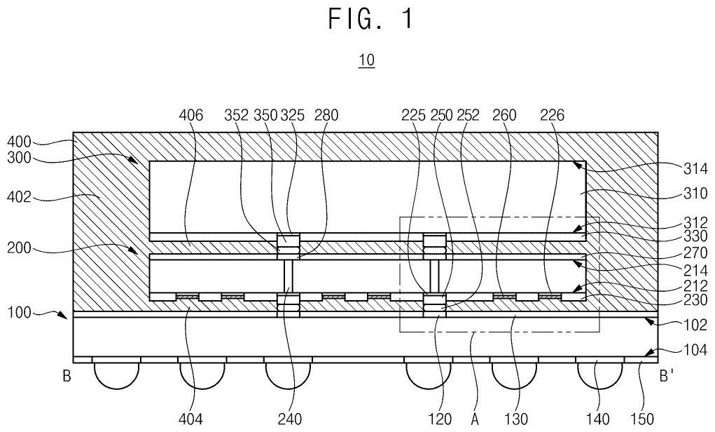

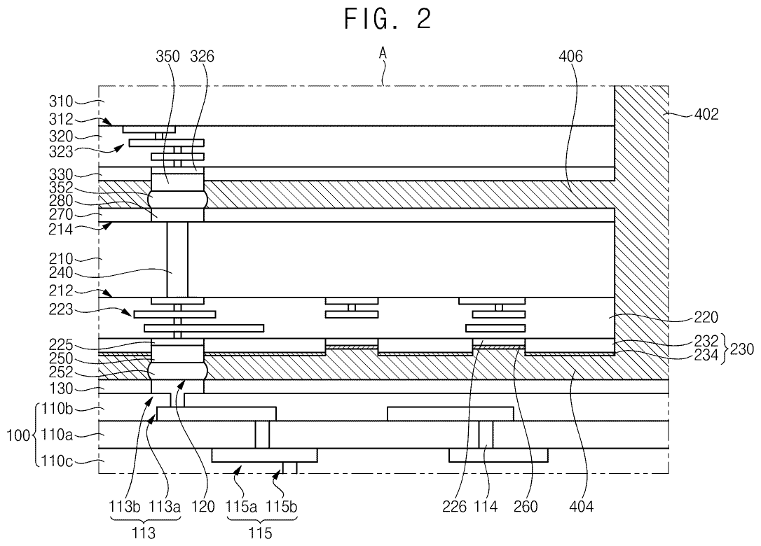

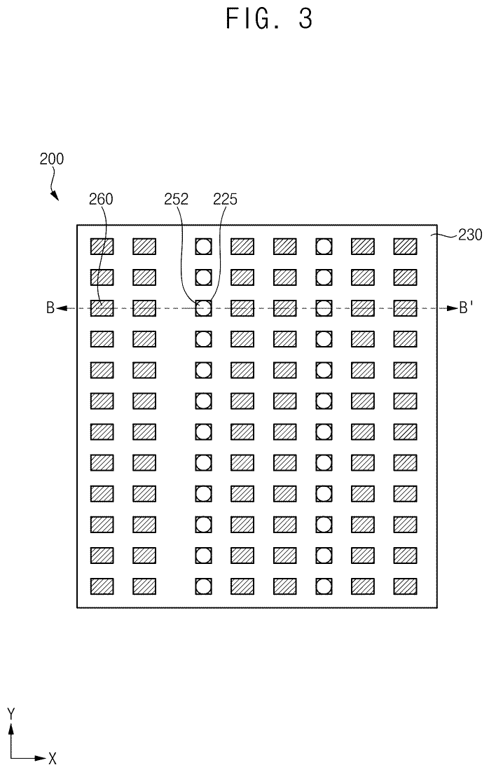

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating a first passivation layer of the first semiconductor chip in FIG. 1. FIG. 1 includes a cross-sectional portion cut along the line B-B′ in FIG. 3.

Referring to FIGS. 1 to 3, a semiconductor package 10 may include a package substrate 100, a first semiconductor chip 200, a second semiconductor chip 300, and a molding member 400. The semiconductor package 10 may further include first and second conductive bumps 252, 352 as conductive connection members that electrically connect the first and second semiconductor chips 200, 300 to the package substrate 100. In addition, the semiconductor package 10 may further include outer connection members 160.

In addition, the semiconductor package 10 may be an EDP (Electronic Data Processing)-TSV package. The semiconductor package 10 may be a multi-chip package (MCP) including different types of semiconductor chips. The semiconductor package 10 may be a system in package (SIP) including a plurality of semiconductor chips stacked or arranged in one package to perform all or most of the functions of an electronic system.

The first semiconductor chip 200 and the second semiconductor chip 300 may include memory chips including memory circuits. For example, the first and second semiconductor chips may include volatile memory devices such SRAM devices, DRAM devices, etc., and nonvolatile memory devices such as flash memory devices, PRAM devices, MRAM devices, RRAM devices, etc. Alternatively, the first semiconductor chip 200 may be a logic chip including logic circuits, and the second semiconductor chip 300 may be a memory chip. The logic chip may be a controller that controls the memory chip.

In this embodiment, the semiconductor package as a multi-chip package is illustrated as including two stacked first and second semiconductor chips 200 and 300. However, example embodiments are not limited thereto, and for example, the semiconductor package may include 4, 8, 12, or 16 stacked semiconductor chips.

In example embodiments, the package substrate 100 may be a substrate having an upper surface 102 and a lower surface 104 opposite to the upper surface 102. For example, the package substrate 100 may include a printed circuit board (PCB) such as a core multilayer substrate. The printed circuit board may be a multilayer circuit board having vias and various circuits therein. Alternatively, the package substrate 100 may include a coreless substrate, a redistribution wiring layer, an interposer, etc. The package substrate 100 may include internal wirings as channels for electrical connection with the first semiconductor chip 200.

The package substrate 100 may have upper substrate pads 120 for electrical connection with the first semiconductor chip 200. The upper substrate pads 120 may be arranged to correspond to first chip pads 250 of the first semiconductor chip 200, respectively. The upper substrate pads 120 may be respectively connected to the wirings. The wirings may extend from the upper surface 102 or within the package substrate 100. For example, at least portions of the wirings may be used as landing pads for the upper substrate pads. Although only a few upper substrate pads are illustrated in the figures, it will be understood that the number, shape, and arrangement of the upper substrate pads are provided by way of example, and example embodiments are not limited thereto.

As illustrated in FIG. 2, in example embodiments, the package substrate 100 may include a core multilayer substrate. For example, the package substrate 100 may include a core layer 110a, an upper insulating layer 110b on an upper surface of the core layer 110a, and a lower insulating layer 110c on a lower surface of the core layer 110a. The package substrate 100 may further include a plurality of through vias 114 penetrating the core layer 110a, a first upper circuit layer 113a on the upper surface of the core layer 110a, a second upper circuit layer 113b provided in the upper insulating layer 110b, a first lower circuit layer 115a on the lower surface of the core layer 110a, and a second lower circuit layer 115b provided in the lower insulating layer 110c. An upper protection layer 130 and a lower protection layer 150, such as solder resist layers, may be formed on the outermost surface of the circuit layers. The upper protection layer 130 may cover the entire upper surface of the insulating layers except for the upper substrate pads 120. The lower protection layer 150 may cover the entire lower surface of the insulating layers except for lower substrate pads 140.

Each of the circuit layers may include a wiring pattern. Each of the wiring patterns may include a pad, a trace, a via, etc. An upper surface of the upper protection layer 130 may be provided as the upper surface 102 of the package substrate 100, and a lower surface of the lower protection layer 150 may be provided as the lower surface 104 of the package substrate 100. At least a portion of the pad of the second upper circuit layer 113b may be provided as the upper substrate pad 120, and at least a portion of the pad of the second lower circuit layer 115b may be provided as the lower substrate pad 140.

In example embodiments, the first semiconductor chip 200 may be placed on the upper surface 102 of the package substrate 100. The first semiconductor chip 200 may be mounted on the package substrate 100 by a flip chip bonding method.

As illustrated in FIG. 2, the first semiconductor chip 200 may include a first substrate 210, a first wiring layer 220, a first passivation layer 230, first chip pads 250 and protective patterns 260. The first semiconductor chip 200 may further include a plurality of through electrodes 240 and a backside insulating layer 270.

The first substrate 210 may have a first surface 212 and a second surface 214 opposite to the first surface 212. The first wiring layer 220 and the first passivation layer 230 may be sequentially stacked on the first surface 212 of the first substrate 210. The first wiring layer 220 may include a plurality of insulating layers, upper wirings 223 in the insulating layers, and first redistribution pads 225 and second redistribution pads 226 as uppermost wirings.

The first passivation layer 230 may be formed on the first wiring layer 220. The first passivation layer 230 may expose at least portions of the first redistribution pads 225 and at least portions of the second redistribution pads 226. For example, the first passivation layer 230 may include a first protection layer 232 and a second protection layer 234 that are sequentially stacked. The first protection layer 232 may include silicon oxide such as TEOS. The second protection layer 234 may include nitride such as silicon nitride (SiN). A thickness of the second protection layer 234 may be less than a thickness of the first protection layer 232. Since the second protection layer 234 including silicon nitride has a relatively thin thickness, a thickness of the first semiconductor chip 200 may be reduced.

The through electrode as a through silicon via (TSV) 240 may be provided to vertically penetrate the first substrate 210. The through electrode 240 may contact the lowermost wiring of the upper wirings 223. Accordingly, the through electrode 240 may be electrically connected to the first redistribution pad 225 by the upper wirings 223.

The first redistribution pads 225 may be electrically connected to circuit elements in the first surface 212 of the first substrate 210 through the upper wirings 223. The second redistribution pads 226 may be dummy pads to which no electrical signal is transmitted. The second redistribution pads 226 may not be electrically connected to the circuit elements or the through electrode.

The first chip pads 250 may be provided on portions of the first redistribution pads 225 exposed by the first passivation layer 230 respectively. The protective patterns 260 may be provided on portions of the second redistribution pads 226 exposed by the first passivation layer 230 respectively.

An area of the second redistribution pad 226 exposed by the first passivation layer 230 may be the same as or greater than an area of the first redistribution pad 225 exposed by the first passivation layer 230. The exposed area, shape, arrangement, etc. of the second redistribution pad 226 may not be limited thereto. For example, the second redistribution pads 226 may be arranged in various sizes and shapes in an area excluding the first redistribution pads 225.

The first chip pads 250 may be formed by a plating process. For example, the first chip pad 250 may include copper (Cu), aluminum (Al), tungsten (W), nickel (Ni), molybdenum (Mo), gold (Au), silver (Ag), chromium (Cr), tin (Sn), titanium (Ti), etc. Although not illustrated in the figures, a plating layer may be formed on the first chip pad 250. The plating layer may include a different metal from the first chip pad. For example, the plating layer may include gold (Au). The first chip pad 250 may have a thickness of 2 μm to 10 μm.

In example embodiments, the protective patterns 260 may be formed by a coating process, a surface treatment process, etc. The protective patterns 260 may be formed by coating an organic layer on the exposed portions of the second redistribution pads 226. The protective pattern 260 may be formed by chemically reacting the exposed surface of the second redistribution pad 226 with an organic compound. For example, the protective pattern 260 may include an organic solderability preservative. The protective pattern 260 having a thin and uniform layer may be formed on the second redistribution pad 226 by chemically reacting an organic compound such as alkylbenzimidazole on the exposed surface of the second redistribution pad 226. The protective pattern 260 may have a thickness of 0.2 μm to 1.0 μm. In addition, the protective patterns 260 may be formed on the uppermost insulating layer of the first wiring layer 220 or on bottom surfaces of the openings formed in the first passivation layer 230.

As illustrated in FIG. 3, the first chip pads 250 may be arranged to be spaced apart in a first direction (X direction). The first chip pads 250 may be arranged to be spaced apart in a second direction (Y direction) perpendicular to the first direction. The protective patterns 260 may be arranged in both sides of the first chip pad 250 or between the first chip pads 250. The sizes, shapes, arrangements, etc. of the protective patterns 260 may not be limited thereto. For example, the protective patterns 260 may be arranged to have various sizes and shapes in an area excluding the first chip pads 250.

The backside insulation layer 270 as a passivation layer may be provided on the second surface 214 of the first substrate 210. First bonding pads 280 may be provided in the backside insulation layer 270. The first bonding pad 280 may be electrically connected to the through electrode 240. The first bonding pad 280 may be disposed on the exposed surface of the through electrode 240. The backside insulating layer 270 may include silicon oxide, carbon-doped silicon oxide, silicon carbon nitride (SiCN), etc. Accordingly, the first chip pad 250 and the first bonding pad 280 may be electrically connected to each other by the through electrode 240.

First conductive bumps 252 may be formed on the first chip pads 250 respectively. For example, the first conductive bumps 252 may be formed by a plating process. Alternatively, the first conductive bumps may be formed by a screen printing method, a deposition method, or the like. The first conductive bumps may include solder bumps.

The first semiconductor chip 200 may be mounted on the package substrate 100 via the first conductive bumps 252. The first semiconductor chip 200 may be arranged such that the first surface 212 of the first substrate 210 on which the first chip pads 250 are formed faces the package substrate 100. The first chip pads 250 of the first semiconductor chip 200 may be electrically connected to the upper substrate pads 120 of the package substrate 100 by the first conductive bumps 252. A gap may be formed between the first semiconductor chip 200 and the package substrate 100.

In example embodiments, a second semiconductor chip 300 may be stacked on the first semiconductor chip 200. The second semiconductor chip 300 may be mounted on the first semiconductor chip 200 by a flip chip bonding method.

As illustrated in FIG. 2, the second semiconductor chip 300 may include a second substrate 310, a second wiring layer 320, a second passivation layer 330, and second chip pads 350.

The second substrate 310 may have a third surface 312 and a fourth surface 314 opposite to the third surface 312. The second wiring layer 320 and the second passivation layer 330 may be sequentially stacked on the third surface 312 of the second substrate 310. The second wiring layer 320 may include a plurality of insulating layers, upper wirings 323 in the insulating layers, and third redistribution pads 325 as uppermost wirings. The second passivation layer 330 may be formed on the second wiring layer 320 and may expose the third redistribution pads 325.

The second chip pads 350 may be provided on the third redistribution pads 325 respectively. The second chip pads 350 may be formed by a plating process. For example, the second chip pad 350 may include copper (Cu), aluminum (Al), tungsten (W), nickel (Ni), molybdenum (Mo), gold (Au), silver (Ag), chromium (Cr), tin (Sn), titanium (Ti), etc. Although not illustrated in the figures, a plating layer may be formed on the second chip pad 350. The plating layer may include a different metal from the second chip pad. For example, the plating layer may include gold (Au).

Second conductive bumps 352 may be provided on the second chip pads 350 respectively. For example, the second conductive bumps 352 may be formed by a plating process. Alternatively, the second conductive bumps may be formed by a screen printing method, a deposition method, or the like. The second conductive bumps may include solder bumps.

The second semiconductor chip 300 may be arranged such that the third surface 312 of the second substrate 310 on which the second chip pads 350 are formed faces the first semiconductor chip 200. The second chip pads 350 of the second semiconductor chip 300 may be electrically connected to the first bonding pads 280 of the first semiconductor chip 200 by the second conductive bumps 352. A gap may be formed between the second semiconductor chip 300 and the first semiconductor chip 200.

The thickness of the first semiconductor chip 200 may be less than a thickness of the second semiconductor chip 300. For example, the thickness of the first semiconductor chip 200 may be within a range of 70 μm to 100 μm. The thickness of the second semiconductor chip 300 may be within a range of 150 μm to 300 μm. A planar area of the first semiconductor chip 200 may be smaller than a planar area of the package substrate 100. When viewed in plan view, the first semiconductor chip 200 may be placed within the package substrate 100. A planar area of the second semiconductor chip 300 may be smaller than the planar area of the package substrate 100. The second semiconductor chip 300 may be arranged to overlap the first semiconductor chip 200.

In example embodiments, the molding member 400 may cover the first semiconductor chip 200 and the second semiconductor chip 300 on the package substrate 100.

For example, the molding member 400 may include a polymer material such as epoxy molding compounds (EMC). The molding member 400 may be formed by a molded underfill (MUF) process using an epoxy material sealant. The molding member 400 may include a first molding portion 402 covering side surfaces of the first and second semiconductor chips 200, 300, a second molding portion 404 filling a space between the package substrate 100 and the first semiconductor chip 200, and a third molding portion 406 filling a space between the first semiconductor chip 200 and the second semiconductor chip 300.

As illustrated in FIG. 2, the second molding portion 404 of the molding member 400 may fill the space between the package substrate 100 and the first semiconductor chip 200 and may cover the protective patterns 260 of the first semiconductor chip 200. The second molding portion 404 may be in direct contact with the protective patterns 260 exposed by the first passivation layer 230.

In example embodiments, the lower substrate pads 140 may be provided on the lower surface 104 of the package substrate 100. The lower substrate pads 140 may be exposed by the lower protection layer 150. Outer connection members 160 for electrical connection with an external device may be respectively disposed on the lower substrate pads 140. For example, the outer connection member 160 may be a solder ball. The semiconductor package 10 may be mounted on a module substrate (not illustrated) via the solder balls to form a memory module.

As mentioned above, the semiconductor package 10 may include the first semiconductor chip 200 and the second semiconductor chip 300 sequentially stacked on the package substrate 100. The first semiconductor chip 200 may include the first passivation layer 230 that is provided on the first surface 212 of the first substrate 210 and exposes the first chip pads 250 and the protective patterns 260. The first semiconductor chip 200 may be arranged such that the first surface 212 faces the package substrate 100 and may be stacked on the package substrate 100 via the first conductive bumps 252 that are formed on the first chip pads 250 respectively. The portion 404 of the molding member 400 including EMC may fill the space between the package substrate 100 and the first semiconductor chip 200 and may be in contact with the protective patterns 260.

The second protection layer 234 as the outermost protection layer of the first passivation layer 230 may include silicon nitride (SiN). Since silicon nitride (SiN) has relatively low interfacial bonding strength with EMC, peeling defects may occur in a hygroscopic environment. The protective patterns 260 including organic solderability preservative may react with epoxy to form a strong bond. Accordingly, the protective patterns 260 may come into contact with the second molding portion 404 to increase the bonding strength between the silicon nitride (SiN) and the EMC interface, thereby preventing peeling defects.

Hereinafter, a method of manufacturing the semiconductor package of FIG. 1 will be described.

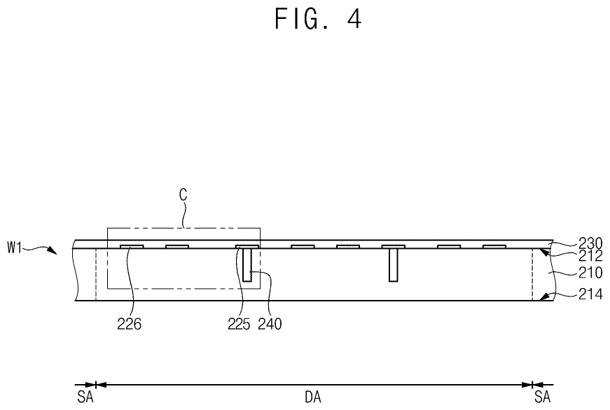

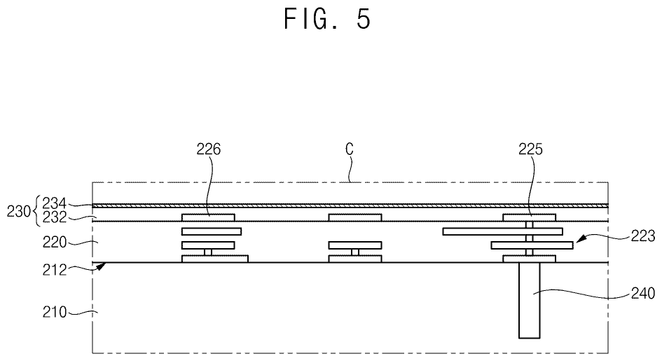

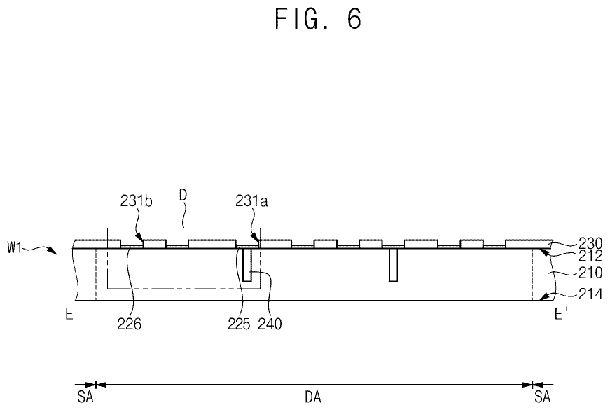

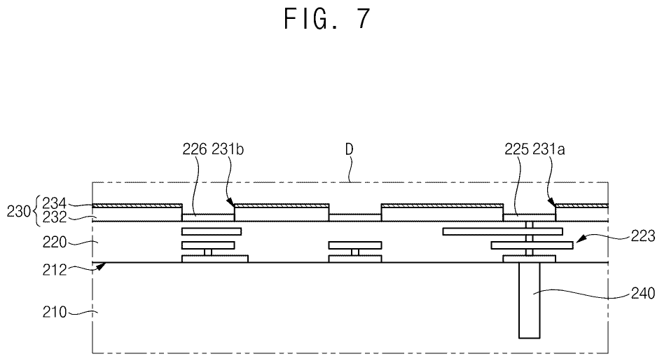

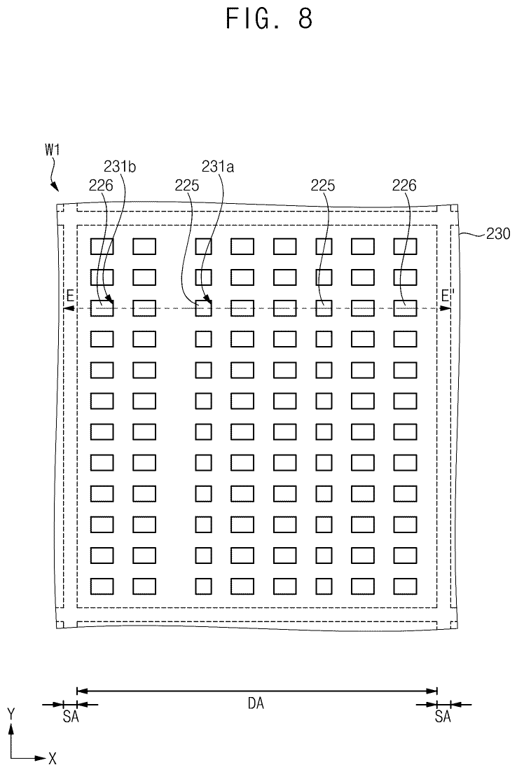

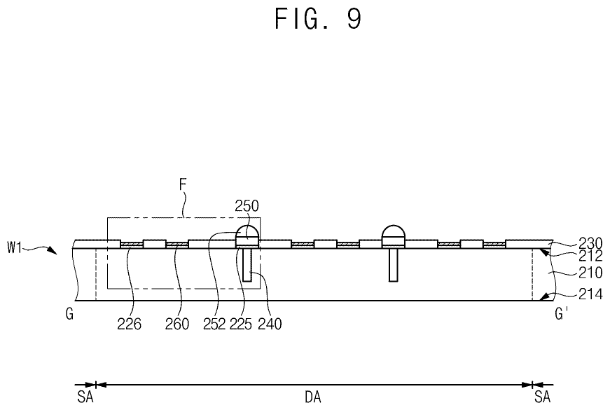

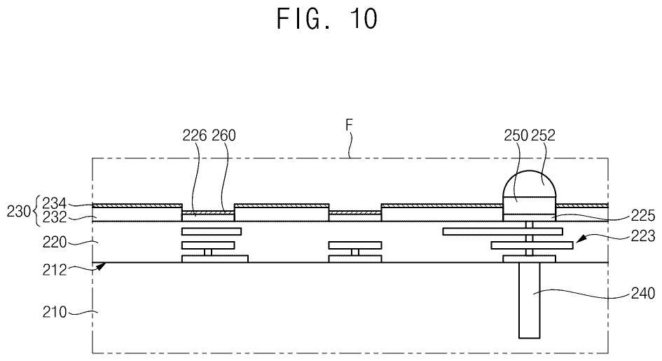

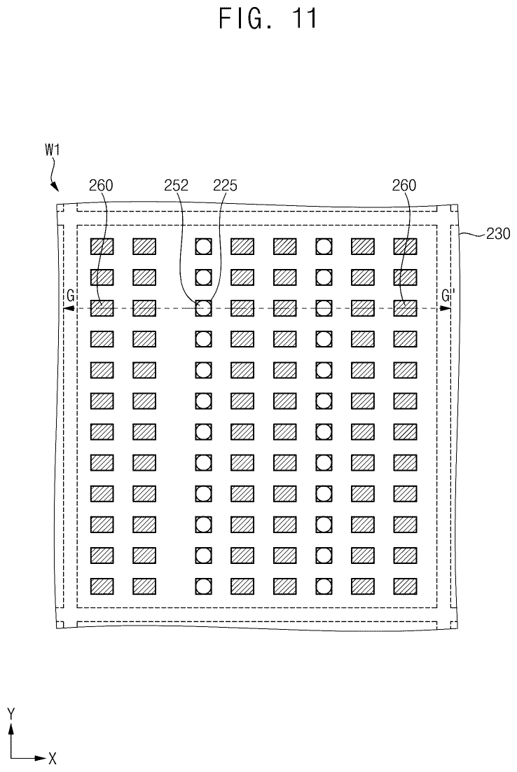

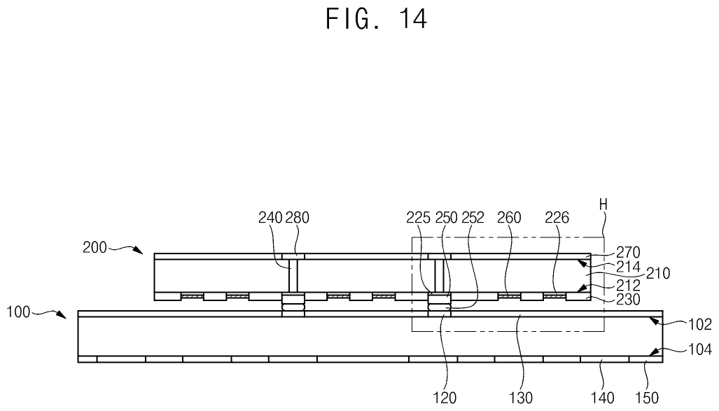

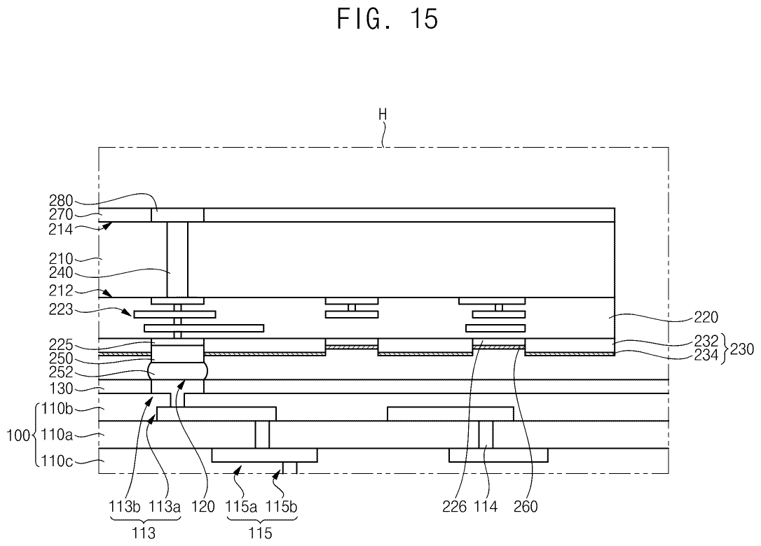

FIGS. 4 to 18 are views illustrating a method of manufacturing a semiconductor package in accordance with example embodiments. FIGS. 4, 6, 9, 12 to 14, and 16 to 18 are cross-sectional views illustrating a method for manufacturing a semiconductor package in accordance with example embodiments. FIG. 5 is an enlarged cross-sectional view illustrating portion ‘C’ in FIG. 4. FIG. 7 is an enlarged cross-sectional view illustrating portion ‘D’ in FIG. 6. FIG. 8 is a plan view of FIG. 6. FIG. 6 is a cross-sectional view taken along line E-E′ in FIG. 8. FIG. 10 is an enlarged cross-sectional view illustrating portion ‘F’ in FIG. 9. FIG. 11 is a plan view of FIG. 9. FIG. 9 is a cross-sectional view taken along the line G-G′ in FIG. 11. FIG. 15 is an enlarged cross-sectional view illustrating portion ‘H’ in FIG. 14.

Referring to FIGS. 4 and 5, a first wafer W1 including a plurality of first semiconductor chips (dies) are formed therein may be provided.

In example embodiments, the first wafer W1 may include a first substrate 210 having a first surface 212 and a second surface 214 opposite to the first surface 212. The first substrate 210 may include a die region DA and a scribe lane region SA surrounding the die region DA. The first substrate 210 may be cut along the scribe lane region SA that divides the plurality of die regions DA of the first wafer W1 by a following sawing process to be individualized into a plurality of first semiconductor chips.

Circuit elements may be formed in the die region DA on the first surface 212 of the first substrate 210. The circuit element may include a plurality of memory devices. Examples of the memory elements may include volatile semiconductor memory devices and nonvolatile semiconductor memory devices. Examples of the volatile semiconductor memory devices may include DRAM, SRAM, etc. Examples of the nonvolatile semiconductor memory devices may include EPROM, EEPROM, Flash EEPROM, etc.

For example, the first substrate 210 may include silicon, germanium, silicon-germanium, or III-V compounds, e.g., GaP, GaAs, GaSb, etc. In some embodiments, the first substrate 210 may be a silicon-on-insulator (SOI) substrate, or a germanium-on-insulator (GOI) substrate.

The circuit elements may include, for example, transistors, capacitors, wiring structures, etc. The circuit elements may be formed on the first surface 212 of the first substrate 210 by performing a Fab process called a Front End of Line (FEOL) process for manufacturing semiconductor devices. A surface of the first substrate on which the FEOL process is performed may be referred to as a front side surface of the first substrate, and a surface opposite to the front side surface may be referred to as a backside surface. An insulation interlayer covering the circuit elements may be formed on the first surface 212 of the first substrate 210.

In example embodiments, the first wafer W1 may include a first wiring layer 220 and a first passivation layer 230 provided on the first substrate 210. The first wiring layer 220 and the first passivation layer 230 may be stacked on the first surface 212 of the first substrate 210. The first wiring layer may be formed by performing a wiring process called a back-end-of-line (BEOL) process.

The first wiring layer 220 may include a plurality of insulating layers, upper wirings 223 in the insulating layers, and first redistribution pads 225 and second redistribution pads 226 as uppermost wirings. For example, the insulating layers may be formed to include oxides such as silicon oxide, carbon-doped oxide, fluorine-doped oxide, etc. The upper wirings and the first and second redistribution pads may include a metal material such as aluminum (Al), copper (Cu), etc.

The first passivation layer 230 may be formed on the first wiring layer 220 and may cover the first redistribution pads 225 and the second redistribution pads 226. For example, the first passivation layer 230 may include a first protection layer 232 and a second protection layer 234 that are sequentially stacked. The first protection layer 232 may include silicon oxide such as TEOS. The second protection layer 234 may include nitride such as silicon nitride (SiN). A thickness of the second protection layer 234 may be less than a thickness of the first protection layer 232. The second protection layer 234 including silicon nitride may have a relatively thin thickness. Accordingly, the overall thickness of the first semiconductor chip may be reduced.

A through electrode such as through silicon via (TSV) 240 may vertically penetrate the insulation interlayer and extend from the first surface 212 of the first substrate 210 to a predetermined depth. The through electrode 240 may contact the lowest wiring of the upper wirings 223. Accordingly, the through electrode 240 may be electrically connected to the first redistribution pad 225 by the upper wirings 223.

A liner layer may be provided on an outer surface of the through electrode 240. The liner layer may include silicon oxide or carbon-doped silicon oxide. The liner layer may electrically insulate the through electrode 240 from the first substrate 210 and the first wiring layer 220. The through electrode 240 may include a metal material. For example, the metal material may include copper (Cu).

The first redistribution pads 225 may be electrically connected to the circuit elements through the upper wirings 223 and contact plugs in the insulation interlayer. As described below, a first chip pad may be formed on at least a portion of the first redistribution pad 225 to be electrically connected to an external device. The second redistribution pads 226 may be dummy pads to which no electrical signal is transmitted. The second redistribution pads 226 may not be electrically connected to the circuit elements or the through electrode.

The number, size, arrangement, etc. of the upper wirings of the first wiring layer and the first and second redistribution pads are provided as examples, and it will be understood that example embodiments are not limited thereto.

Referring to FIGS. 6 to 11, first chip pads 250 may be formed on the first redistribution pads 225 on the first wiring layer 220 respectively, and first conductive bumps 252 may be formed on the first chip pads 250 respectively. In addition, protective patterns 260 may be formed on the second redistribution pads 226 on the first wiring layer 220, respectively.

As illustrated in FIGS. 6 to 8, portions of the first passivation layer 230 may be removed to form first openings 231a that expose at least portions of the first redistribution pads 225 and second openings 231b that expose at least portions of the second redistribution pads 226.

In example embodiments, a photoresist film may be formed on the first passivation layer 230, an exposure process may be performed to form a photoresist pattern having openings that exposing portions of the first passivation layer 230, and the first passivation layer 230 may be partially removed using the photoresist pattern as an etching mask to form the first and second openings 231a, 231b.

An exposed area of the second redistribution pad 226 may be the same as or greater than an exposed area of the first redistribution pad 225. The exposed area, shape, arrangement, etc. of the second redistribution pad 226 may not be limited thereto. For example, the second redistribution pads 226 may be arranged in various sizes within the die region DA excluding the first redistribution pads 225.

As illustrated in FIGS. 9 to 11, the first chip pads 250 may be formed on the exposed portions of the first redistribution pads 225, and the protective patterns 260 may be formed on the exposed portions of the second redistribution pads 226.

In example embodiments, the first chip pads 250 may be formed by a plating process. For example, the first chip pad 250 may include copper (Cu), aluminum (Al), tungsten (W), nickel (Ni), molybdenum (Mo), gold (Au), silver (Ag), chromium (Cr), tin (Sn), titanium (Ti), etc. Although not illustrated in the figures, a plating layer may be formed on the first chip pad 250. The plating layer may include a different metal from the first chip pad. For example, the plating layer may include gold (Au). The first chip pad 250 may be formed to have a thickness of 2 μm to 10 μm.

In example embodiments, the protective patterns 260 may be formed by a coating process, a surface treatment process, etc. The protective patterns 260 may be formed by coating an organic layer on the exposed portions of the second redistribution pads 226. The protective pattern 260 may be formed by chemically reacting the exposed surface of the second redistribution pad 226 with an organic compound. For example, the protective pattern 260 may include an organic solderability preservative. The protective pattern 260 having a thin and uniform layer may be formed on the second redistribution pad 226 by chemically reacting an organic compound such as alkylbenzimidazole on the exposed surface of the second redistribution pad 226. The protective pattern 260 may have a thickness of 0.2 μm to 1.0 μm. In addition, the protective patterns 260 may be formed on the uppermost insulating layer of the first wiring layer 220 or on bottom surfaces of the openings formed in the first passivation layer 230.

For example, in case that the first chip pads 250 are formed before the protective patterns 260, the first openings 231a may be formed, the first chip pads 250 may be formed on the first redistribution pads 225 exposed by the first openings 231a, the second openings 231b may be formed, and then, the protective patterns 260 may be formed on the second redistribution pads 226b exposed by the second openings 231b. Alternatively, in case that the protective patterns 260 are formed before the first chip pads 250, the second openings 231b may be formed, the protective patterns 260 may be formed on the second redistribution pads 226 exposed by the second openings 231b, the first openings 231a may be formed, and then, the first chip pads 250 may be formed on the first redistribution pads 225 exposed by the first openings 231a.

Then, the first conductive bumps 252 may be formed on the first chip pads 250 respectively. For example, the first conductive bumps 252 may be formed by a plating process. In particular, a seed layer may be formed on the first chip pads 250 on the first passivation layer 230, a photoresist pattern having openings that expose portions of the seed layer may be formed, the openings of the photoresist pattern may be filled with a conductive material, the photoresist pattern may be removed, and then, a reflow process may be performed to form the first conductive bumps. Alternatively, the first conductive bumps may be formed by a screen printing method, a deposition method, or the like. The first conductive bumps may include solder bumps.

Accordingly, the first passivation layer 230 may expose the first chip pads 250 on the first redistribution pads 225 and the protective patterns 260 on the second redistribution pads 226 on the first wiring layer 220, respectively.

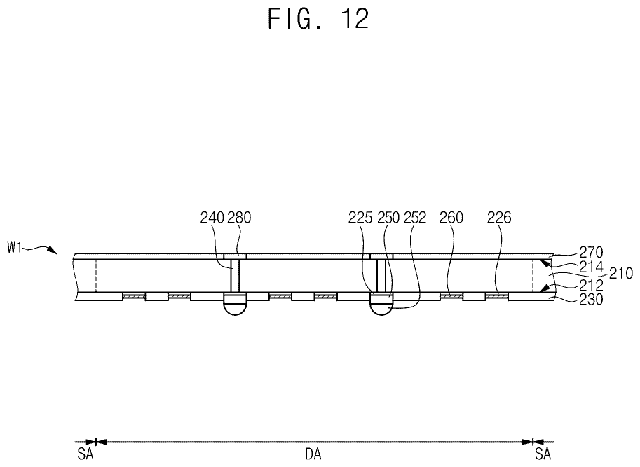

Referring to FIG. 12, a backside insulating layer 270 having first bonding pads 280 in an outer surface thereof may be formed on the second surface 214 of the first substrate 210.

First, the structure of FIG. 9 may be turned over, and the second surface 214 of the first substrate 210 may be partially removed to expose end portions of the through electrodes 240.

In example embodiments, first, a grinding process such as a back lap process may be performed to partially remove the second surface 214 of the first substrate 210, and then an etching process such as a silicon recess process may be performed to expose the end portions of the through electrodes 240. Accordingly, a thickness of the first substrate 210 may be reduced to a desired thickness. For example, the first substrate 210 may have a thickness range of about 30 μm to 70 μm.

The back lap process may grind the entire second surface 214 of the first substrate 210. The silicon recess process may selectively etch only silicon in the second surface 214 of the first substrate 210. The etching process may be an isotropic dry etching process. The etching process may include a plasma etching process, etc. The plasma etching process may be performed using inductively coupled plasma, capacitively coupled plasma, microwave plasma, etc.

Then, the backside insulating layer 270 as a passivation layer having the first bonding pads 280 electrically connected to the through electrode 240 may be formed on the second surface 214 of the first substrate 210.

For example, after forming the backside insulating layer 270 on the second surface 214 of the first substrate 210, an opening that exposes one end portion of the through electrode 240 may be formed in the backside insulating layer 270, and a plating process may be performed to form the first bonding pad 280 in the opening. The first bonding pad 280 may be disposed on the exposed surface of the through electrode 240. The backside insulating layer 270 may include silicon oxide, carbon-doped silicon oxide, silicon carbon nitride (SiCN), etc. Accordingly, the first chip pad 250 and the first bonding pad 280 may be electrically connected to each other by the through electrode 240.

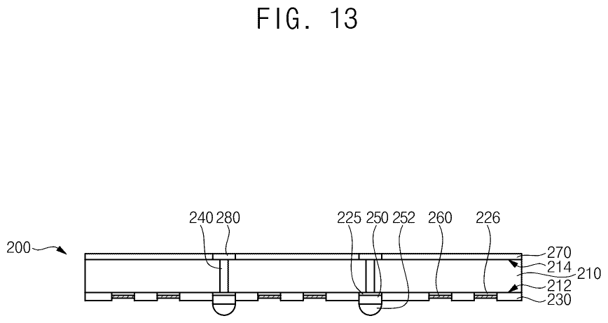

Referring to FIG. 13, the first wafer W1 may be cut along the scribe lane region SA to form an individualized first semiconductor chip 200. The first wafer W1 may be cut by a sawing process.

Since silicon nitride (SiN) has a relatively low coefficient of thermal expansion (CTE) compared to silicon and has a relatively thin layer, SiN may be used as the second protection layer 234, which is the outermost insulating layer of the first passivation layer 230. A thickness of the first semiconductor chip 200 may be within a range of 70 μm to 100 μm.

Referring to FIGS. 14 and 15, the first semiconductor chip 200 may be stacked on a package substrate 100.

In example embodiments, the package substrate 100 may have an upper surface 102 and a lower surface 104 opposite to the upper surface 102. The package substrate 100 may include internal wirings as channels for electrical connection with the first semiconductor chip 200.

The package substrate 100 may have upper substrate pads 120 for electrical connection with the first semiconductor chip 200. The upper substrate pads 120 may be arranged to correspond to the first chip pads 250 of the first semiconductor chip 200, respectively. The upper substrate pads 120 may be connected to the wirings respectively. The wirings may extend from the upper surface 102 or within the package substrate 100. For example, at least portions of the wirings may be used as landing pads for the upper substrate pads. Although only a few upper substrate pads are illustrated in the figures, it will be understood that the number, shape, and arrangement of the upper substrate pads are provided as examples, and example embodiments are not limited thereto.

In example embodiments, the first semiconductor chip 200 may be mounted on the package substrate 100 via the first conductive bumps 252. The first semiconductor chip 200 may be arranged such that the first surface 212 of the first substrate 210 on which the first chip pads 250 are formed faces the package substrate 100, and a reflow process may be performed to bond the first conductive bumps 252 onto the upper substrate pads 120. The first chip pads 250 of the first semiconductor chip 200 may be electrically connected to the upper substrate pads 120 of the package substrate 100 by the first conductive bumps 252 as conductive connecting members. A gap may be formed between the first semiconductor chip 200 and the package substrate 100. The protective patterns 260 on the second redistribution pads 226 may be exposed to the outside.

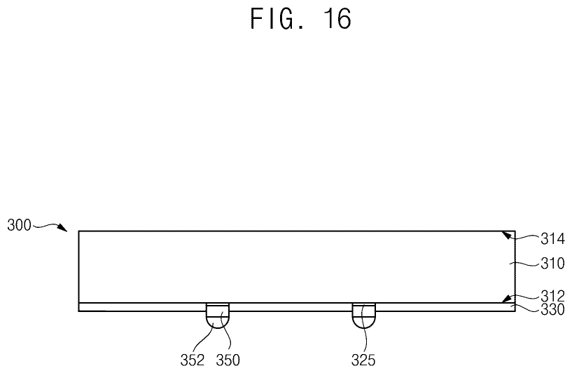

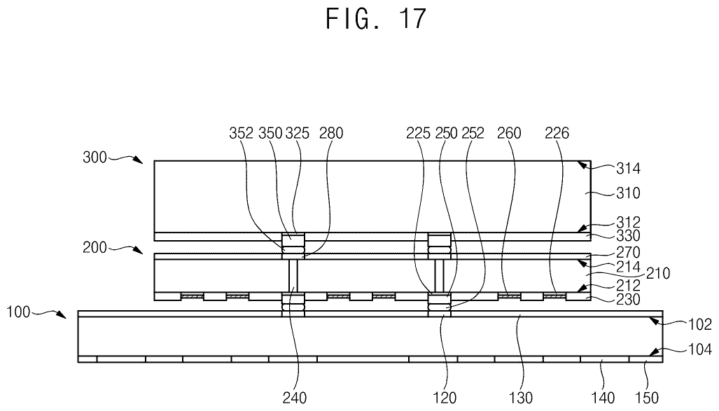

Referring to FIGS. 16 and 17, a second semiconductor chip 300 may be stacked on the first semiconductor chip 200.

As illustrated in FIG. 16, processes the same as or similar to the processes described with reference to FIGS. 4 to 13 may be performed to cut a second wafer along a scribe lane region to form an individualized second semiconductor chip 300. The second semiconductor chip 300 may include a second substrate 310 having a third surface 312 and a fourth surface 314 opposite to the third surface 312, a second wiring layer 320 provided on the third surface 312 and having a third redistribution pad 325, a second chip pad 350 provided on the third redistribution pad 315, and a second conductive bump 352 formed on the second chip pad 350.

The second semiconductor chip may include a memory chip including a memory circuit. For example, the second semiconductor chip may include volatile memory devices such SRAM devices, DRAM devices, etc., and nonvolatile memory devices such as flash memory devices, PRAM devices, MRAM devices, RRAM devices, etc.

A thickness of the second semiconductor chip 300 may be greater than the thickness of the first semiconductor chip 200. For example, the thickness of the second semiconductor chip 300 may be within a range of 150 μm to 300 μm.

As illustrated in FIG. 17, the second semiconductor chip 300 may be stacked on the second semiconductor chip 300 via the second conductive bumps 352. The second semiconductor chip 300 may be arranged such that the third surface 312 of the second substrate 310 on which the second chip pads 350 are formed faces the first semiconductor chip 200, and a reflow process may be performed to bond the second conductive bumps 352 onto the first bonding pads 280. The second chip pads 350 of the second semiconductor chip 300 may be electrically connected to the first bonding pads 280 of the first semiconductor chip 200 by the second conductive bumps 352 as conductive connecting members. A gap may be formed between the second semiconductor chip 300 and the first semiconductor chip 200.

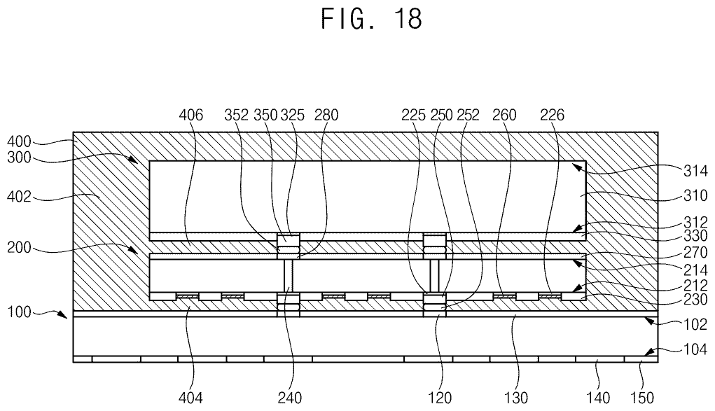

Referring to FIG. 18, a molding member 400 may be formed on the package substrate 100 to cover the first semiconductor chip 200 and the second semiconductor chip 300.

In example embodiments, the molding member 400 may include a polymer material such as epoxy molding compounds (EMC). The molding member 400 may be formed by a molded underfill (MUF) process using an epoxy material sealant. In the molded underfill process, the sealant may have fluidity in a liquefied state, and a first portion of the sealant may be formed to flow between the first semiconductor chip 200 and the package substrate 100 and surround the first conductive bumps 252, and a second portion of the sealant may be formed to flow between the second semiconductor chip 300 and the first semiconductor chip 200 and surround the second conductive bumps 352.

Accordingly, the molding member 400 may include a first molding portion 402 covering side surfaces of the first and second semiconductor chips 200, 300, a second molding portion 404 filling a space between the package substrate 100 and the first semiconductor chip 200, and a third molding portion 406 filling a space between the first semiconductor chip 200 and the second semiconductor chip 300.

The second molding portion 404 of the molding member 400 may fill the space between the package substrate 100 and the first semiconductor chip 200 and may cover the protective patterns 260 of the first semiconductor chip 200. The second molding portion 404 may be in direct contact with the protective patterns 260 exposed by the first passivation layer 230.

The second protection layer 234 as the outermost protection layer of the first passivation layer 230 may include silicon nitride (SiN). Since silicon nitride (SiN) has relatively low interfacial bonding strength with EMC, peeling defects may occur in a hygroscopic environment. In particular, the first passivation layer 230 of the first semiconductor chip 200 may be warped due to high temperature when adjacent to a high temperature heat source during package operation. The protective patterns 260 including organic solderability preservative may react with epoxy to form a strong bond. Accordingly, when the protective patterns 260 come into contact with the second molding portion 404, the bonding strength between the silicon nitride (SiN) and the EMC interface may be increased, thereby preventing peeling defects.

Then, outer connection members 160 (see FIG. 1) may be formed on lower substrate pads 140 on the lower surface 104 of the package substrate 100 to complete a semiconductor package 10 (see FIG. 1).

For example, the outer connection members may include solder balls. The outer connection members may be formed on the lower substrate pads 140 of the lower surface 104 of the package substrate 100 respectively by a solder ball attach process.

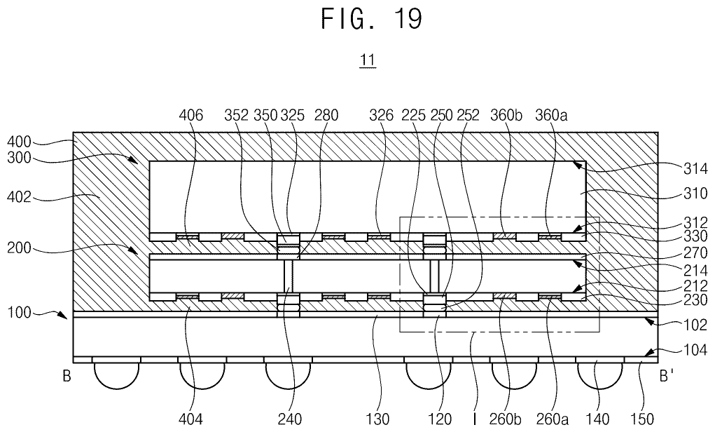

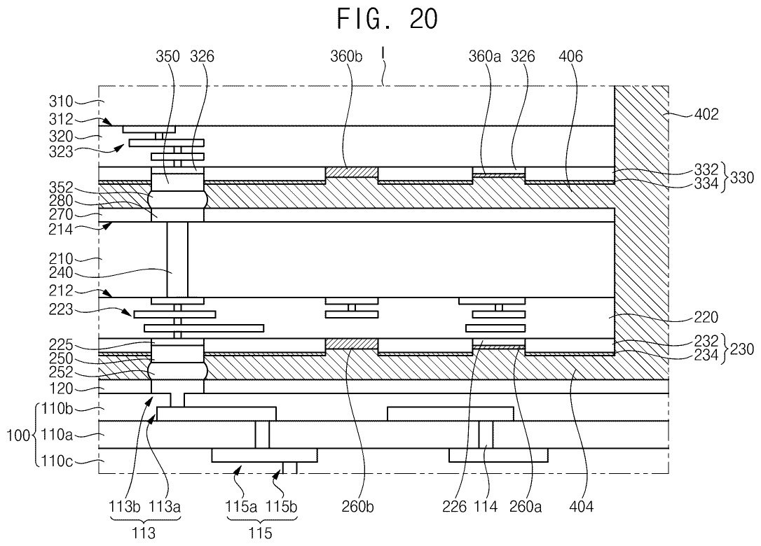

FIG. 19 is a cross-sectional view illustrating a semiconductor package in accordance with example embodiments. FIG. 20 is an enlarged cross-sectional view illustrating portion ‘I” in FIG. 19. The semiconductor package is substantially the same as the semiconductor package described with reference to FIGS. 1 to 3 except for an additional configuration of second, third, and fourth protective patterns. Thus, same reference numerals will be used to refer to the same or like elements and any further repetitive explanation concerning the above elements will be omitted.

Referring to FIGS. 19 and 20, a first semiconductor chip 200 of a semiconductor package 11 may include a first protective pattern 260a and a second protective pattern 260b on a first surface 212 of a first substrate 210. A second semiconductor chip 200 of the semiconductor package 11 may include a third protective pattern 360a and a fourth protective pattern 360b on a third surface 312 of a second substrate 310.

In example embodiments, the first semiconductor chip 200 may include a first substrate 210, a first wiring layer 220, a first passivation layer 230, first chip pads 250, a first protective pattern 260a, and a second protective pattern 260b.

The first protective pattern 260a may be provided on a second redistribution pad 226 exposed by the first passivation layer 230. The second protective pattern 260b may be provided on the uppermost insulating layer of the first wiring layer 220 exposed by the first passivation layer 230. Alternatively, the second protective pattern 260b may be provided on a bottom surface of a first opening formed in the first passivation layer 230. In this case, the first opening may be formed to have a predetermined depth from an outer surface of the first passivation layer 230, and the second protective pattern 260b may be formed on the bottom surface of the first opening.

In example embodiments, the second semiconductor chip 300 may include a second substrate 310, a second wiring layer 320, a second passivation layer 330, second chip pads 350, a third protective pattern 360a, and a fourth protective pattern 360b. The second passivation layer 330 may be formed on the second wiring layer 320. For example, the second passivation layer 330 may include a third protection layer 332 and a fourth protection layer 334 that are sequentially stacked. The third protection layer 332 may include silicon oxide such as TEOS. The fourth protection layer 334 may include nitride such as silicon nitride (SiN).

The second wiring layer 320 may include third redistribution pads 325 and fourth redistribution pads 326 as uppermost wirings. The fourth redistribution pads 326 may be dummy pads to which no electrical signal is transmitted. The fourth redistribution pads 326 may not be electrically connected to circuit elements. The second passivation layer 330 may expose at least portions of the third redistribution pads 325 and at least portions of the fourth redistribution pads 326.

The second chip pads 350 may be respectively provided on the portions of the third redistribution pads 325 exposed by the second passivation layer 330. The third protective patterns 360a may be provided on the fourth redistribution pads 326 exposed by the second passivation layer 330. The fourth protective pattern 360b may be provided on the uppermost insulating layer of the second wiring layer 320 exposed by the second passivation layer 330. Alternatively, the fourth protective pattern 360b may be provided on a bottom surface of a second opening formed in the second passivation layer 330. In this case, the second opening may be formed to have a predetermined depth from an outer surface of the second passivation layer 330, and the fourth protective pattern 360b may be formed on the bottom surface of the second opening.

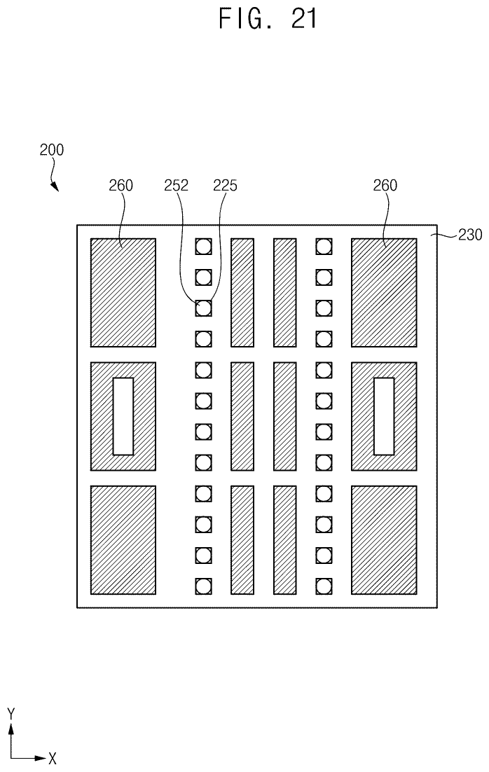

FIG. 21 is a plan view illustrating a first semiconductor chip of a semiconductor package in accordance with example embodiments. The semiconductor package is substantially the same as the semiconductor package described with reference to FIGS. 1 to 3 except for shapes and arrangements of protective patterns. Thus, same reference numerals will be used to refer to the same or like elements and any further repetitive explanation concerning the above elements will be omitted.

Referring to FIG. 21, first chip pads 250 may be arranged to be spaced apart in a first direction (X direction). The first chip pads 250 may be arranged to be spaced apart in a second direction (Y direction) perpendicular to the first direction. The protective patterns 260 may be arranged in both sides of the first chip pad 250 or between the first chip pads 250.

The protective patterns 260 may have rectangular shapes or annular shapes of different sizes. Alternatively, the protection patterns 260 may have circular or oval shapes. The sizes, shapes, arrangements, etc. of the protective patterns 260 may not be limited thereto. For example, the protective patterns 260 may be arranged to have various sizes and shapes in an area excluding the first chip pads 250.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate;
a first semiconductor chip including a first substrate having a first surface and a second surface opposite to the first surface, a through electrode penetrating the first substrate, a first chip pad disposed on the first surface and electrically connected to the through electrode, a protective pattern disposed on the first surface, and a first passivation layer disposed on the first surface and exposing the first chip pad and the protective pattern, wherein the first surface faces the package substrate, and the first semiconductor chip is connected to the package substrate via a first conductive bump disposed on the first chip pad;
a second semiconductor chip stacked on the first semiconductor chip and electrically connected to the through electrode; and
a molding member covering the first semiconductor chip and the second semiconductor chip on the package substrate, the molding member having a first molding portion that is disposed in a space between the package substrate and the first semiconductor chip and contacts the protective pattern.

2. The semiconductor package of claim 1, wherein the protective pattern includes an organic layer.

3. The semiconductor package of claim 2, wherein the protective pattern includes organic solderability preservative.

4. The semiconductor package of claim 1, wherein the protection pattern has a thickness within a range of 0.2 μm to 1.0 μm, and the first semiconductor chip has a thickness within a range of 70 μm to 100 μm.

5. The semiconductor package of claim 1, wherein the first passivation layer includes silicon nitride.

6. The semiconductor package of claim 1, wherein the first molding portion is disposed in an opening of the first passivation layer.

7. The semiconductor package of claim 1, wherein the first semiconductor chip further includes a first wiring layer disposed on the first surface of the first substrate and having a first redistribution pad and a second redistribution pad, and
wherein the first chip pad is disposed on the first redistribution pad, and the protection pattern is disposed on the second redistribution pad.

8. The semiconductor package of claim 1, wherein the second semiconductor chip includes a second substrate having a third surface and a fourth surface opposite to the third surface, a second chip pad disposed on the third surface, and a second passivation layer disposed on the third surface and exposing the second chip pad, wherein the third surface faces the first semiconductor chip, and the second semiconductor chip is connected to the first semiconductor chip via a second conductive bump disposed on the second chip pad.

9. The semiconductor package of claim 8, wherein the molding member has a second molding portion that is disposed in a space between the first semiconductor chip and the second semiconductor chip and surrounds the second conductive bump.

10. The semiconductor package of claim 9, wherein the second semiconductor chip further includes a second protective pattern on the third surface, the second passivation layer exposes the second protective pattern, and the second molding portion is in contact with the second protective pattern.

11. A semiconductor package, comprising:
a package substrate;
a first semiconductor chip including a first substrate, a first wiring layer disposed on a first surface of the first substrate and having a first redistribution pad and a second redistribution pad, a first chip pad disposed on the first redistribution pad, a protective pattern disposed on the second redistribution pad, and a first passivation layer disposed on the first wiring layer and exposing the first chip pad and the protective pattern, wherein the first surface faces the package substrate, and the first semiconductor chip is connected to the package substrate via a first conductive bump disposed on the first chip pad; and
a molding member covering the first semiconductor chip on the package substrate, the molding member having a first molding portion that is disposed in a space between the package substrate and the first semiconductor chip and surrounds the first conductive bump,
wherein the first molding portion of the molding member is in contact with the protective pattern, and
wherein the protective pattern includes an organic layer.

12. The semiconductor package of claim 11, wherein the protective pattern includes organic solderability preservative.

13. The semiconductor package of claim 11, wherein the protective pattern has a thickness within a range of 0.2 μm to 1.0 μm and the first semiconductor chip has a thickness within a range of 70 μm to 100 μm.

14. The semiconductor package of claim 11, wherein the first passivation layer includes silicon nitride.

15. The semiconductor package of claim 14, wherein the first molding portion of the molding member is in contact with the silicon nitride, the organic layer, and the package substrate.

16. The semiconductor package of claim 11, further comprising:
a second semiconductor chip stacked on the first semiconductor chip,
wherein the second semiconductor chip includes a second substrate having a third surface and a fourth surface opposite the third surface, a second chip pad disposed on the third surface, and a second passivation layer disposed on the third surface and exposing the second chip pad,
the third surface faces the first semiconductor chip, and
the second semiconductor chip is connected to the first semiconductor chip via a second conductive bump disposed on the second chip pad.

17. The semiconductor package of claim 16, wherein the molding member is disposed in a space between the first semiconductor chip and the second semiconductor chip and has a second molding portion that surrounds the second conductive bump.

18. The semiconductor package of claim 17, wherein the second semiconductor chip further includes a second protective pattern on the third surface, the second passivation layer exposes the second protective pattern, and the second molding portion is in contact with the second protective pattern.

19. The semiconductor package of claim 11, wherein the first semiconductor chip further includes a through electrode penetrating the first substrate, and
the first redistribution pad is electrically connected to the through electrode.

20. A semiconductor package, comprising:
a package substrate;
a first semiconductor chip including a first substrate, a through electrode penetrating the first substrate, a first wiring layer disposed on a first surface of the first substrate and having a first redistribution pad and a second redistribution pad, and a first chip pad disposed on the first redistribution pad, a protective pattern disposed on the second redistribution pad, and a first passivation layer disposed on the first wiring layer and exposing the first chip pad and the protective pattern, wherein the first surface faces the package substrate, and the first semiconductor chip is connected to the package substrate via a first conductive bump formed on the first chip pad;
a second semiconductor chip including a second substrate, a second chip pad disposed on a third surface of the second substrate, and a second passivation layer disposed on the third surface and exposing the second chip pad, wherein the third surface faces the first semiconductor chip, and the second semiconductor chip is connected to the first semiconductor chip via a second conductive bump disposed on the second chip pad;
a molding member covering the first semiconductor chip and the second semiconductor chip on the package substrate, the molding member having a first molding portion that is disposed in a space between the package substrate and the first semiconductor chip and contacts the protective pattern, and a second molding portion that is disposed in a space between the first semiconductor chip and the second semiconductor chip and surrounds the second conductive bump; and
a plurality of outer connection members disposed on a lower surface of the package substrate.
